(19) United States
(12) Patent Application Publication
(10) Pub. No.: US 2026/0190745 A1
(43) Pub. Date: Jul. 2, 2026

(54) DISPLAY DEVICE

(71) Applicant: LG Display Co., Ltd., Seoul (KR)

(72) Inventors: Deuk Su LEE, Paju-si (KR); Ji Hyun JUNG, Paju-si (KR); Hyang Myoung GWON, Paju-si (KR); Ru Da RHE, Paju-si (KR)

(73) Assignee: LG Display Co., Ltd., Seoul (KR)

(21) Appl. No.: 19/436,656

(22) Filed: Dec. 30, 2025

(30) Foreign Application Priority Data
Dec. 31, 2024 (KR) 10-2024-0203023

(51) Int. Cl. H10K 59/40; G06F 3/044; H10K 59/80; H10K 102/00

(52) U.S. Cl. CPC H10K 59/40; G06F 3/0443; G06F 3/0446; H10K 59/873; H10K 59/8792; H10K 2102/351

(57) ABSTRACT

A display device can include a plurality of pixels disposed on a substrate, an encapsulation unit disposed on the plurality of pixels, and a plurality of touch electrodes disposed on the encapsulation unit. The plurality of touch electrodes include a lower electrode unit having a plurality of first opening holes that respectively expose the plurality of pixels, and an upper electrode unit disposed on the lower electrode unit with a smaller area than the lower electrode unit.

### CROSS-REFERENCE TO RELATED APPLICATION

This application claims priority to and the benefit of Korean Patent Application No. 10-2024-0203023, filed in the Republic of Korea on Dec. 31, 2024, the disclosure of which is hereby expressly incorporated by reference in its entirety.

### BACKGROUND

### 1. Field of the Invention

Embodiments of the present disclosure relate to a touch display device.

### 2. Discussion of Related Art

In order to provide various functions to a user, a display device recognizes a touch of a user's finger or pen on a display panel and performs input processing based on the recognized touch.

The display device can include a plurality of touch electrodes disposed on the display panel. The display device can drive the plurality of touch electrodes and detect a change in capacitance which occurs when the user touches the display panel, thereby sensing a user's touch.

In the display device, an area of the touch electrode needs to be increased to increase touch sensing sensitivity, but there can be problems in that the touch electrodes may be recognized from the outside and an area of the touch electrodes can be limited.

### SUMMARY OF THE INVENTION

Embodiments of the present disclosure provide a display device including a touch electrode with improved reflective visibility and an increased area.

Embodiments of the present disclosure provide a display device which addresses the limitations and disadvantages associated with the related art.

The objects of the present disclosure are not limited to the above-described objects, and other objects that are not mentioned will be clearly understood by those skilled in the art from the following description.

A display device according to one aspect of the present disclosure includes a plurality of pixels disposed on a substrate, an encapsulation unit disposed on the plurality of pixels, and a plurality of touch electrodes disposed on the encapsulation unit, wherein the plurality of touch electrodes include a lower electrode unit in which a plurality of first opening holes that respectively expose the plurality of pixels are disposed, and an upper electrode unit disposed on the lower electrode unit with a smaller area than the lower electrode unit.

### BRIEF DESCRIPTION OF THE DRAWINGS

The following drawings attached to this specification illustrate preferred embodiments of the present invention and, together with the detailed description of the invention to be described below, serve to further understand the technical idea of the present invention, and therefore the present invention should not be construed as being limited to matters described in such drawings, in which:

FIG. 1 is a conceptual diagram of a display device according to one or more embodiments of the present disclosure;

FIG. 2 is a conceptual diagram of a touch panel according to one or more embodiments of the present disclosure;

FIG. 3 is a conceptual diagram of a touch electrode according to one embodiment of the present disclosure;

FIG. 4 is a partially enlarged view of FIG. 3 according to an example of the present disclosure;

FIG. 5 is a view showing a mesh-type touch electrode;

FIG. 6A is a cross-sectional view taken along line A-A′ in FIG. 4 according to an example of the present disclosure;

FIG. 6B is an enlarged view of region C in FIG. 6A according to an example of the present disclosure;

FIG. 7A is a cross-sectional view taken along line A-A′ in FIG. 4 according to another embodiment of the present disclosure;

FIG. 7B is an enlarged view of region D in FIG. 7A according to an example of the present disclosure;

FIG. 8 is a cross-sectional view taken along line B-B′ in FIG. 4 according to an example of the present disclosure; and

FIGS. 9 to 11 are views showing various modified examples of a second opening hole formed in a touch electrode according to one embodiment of the present disclosure.

### DETAILED DESCRIPTION OF THE EMBODIMENTS

Advantages and features of the present invention and implementation methods thereof will be clarified through the following embodiments of the present disclosure described with reference to the accompanying drawings. However, the present invention is not limited to the embodiments described below and can be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and thus the present invention is not limited to matters illustrated in the drawings. Throughout the specification, like reference numerals refer to substantially like components. Further, in describing the present invention, detailed descriptions of well-known technologies will be omitted when it is determined that they can unnecessarily obscure the gist of the present invention.

Terms such as “including,” “having,” and “composed of” used herein are intended to allow other elements to be added unless the terms are used with the term “only.” Any references to the singular can include the plural unless expressly stated otherwise.

Components are interpreted to include an ordinary error range even if not expressly stated.

When positional or interconnection relationships between two parts is described as “on,” “above,” “below,” “over,” “under,” and “next to,” and the like, one or more parts can be interposed therebetween unless the term “immediately” or “directly” is used in the expression.

When the temporal order relationship is described using the terms such as “after,” “subsequent to,” “next,” “before,” and the like, a case that is not continuous can be included unless the term “immediately” or “directly” is used.

Although the terms such as first, second, and the like are used to distinguish the components, the functions or structures of these components are not limited by the ordinal number before the component or the name of the component.

The following embodiments of the present disclosure can be partially or entirely bonded to or combined with each other and can be interoperated and performed in technically various ways. Each of the embodiments of the present disclosure can be independently operable with respect to each other and can be implemented together in related relationships.

In a display device according to one or more embodiments of the present invention, a pixel circuit and a gate driving circuit can include a plurality of transistors. The transistors can be oxide thin-film transistors (TFTs) including an oxide semiconductor, or low-temperature polysilicon (LTPS) TFTs including LTPS.

According to aspects of the present invention, the transistors are three-electrode elements each including a gate, a source, and a drain. The source is an electrode that provides carriers to the transistor. The carriers in the transistor start to flow from the source. The drain is an electrode through which the carriers are discharged from the transistor to the outside. In the transistor, carriers flow from the source to the drain. In the case of an n-channel transistor, carriers are electrons, and thus a source voltage is lower than a drain voltage so that the electrons flow from the source to the drain. In the n-channel transistor, current flows from the drain to the source. In the case of a p-channel transistor, carriers are holes, and thus a source voltage is higher than a drain voltage so that the holes flow from the source to the drain. In the p-channel transistor, since the holes flow from the source to the drain, current flows from the source to the drain. It should be noted that the source and the drain of the transistor are not fixed in position. For example, the source and the drain are interchangeable depending on the applied voltage. Accordingly, the present invention is not limited by the source and the drain of the transistor. In the following description, the source and the drain of the transistor will be referred to as a first electrode and a second electrode.

According to aspects of the present invention, a gate signal can swing between a gate-on voltage and a gate-off voltage. The transistor is turned on in response to the gate-on voltage and turned off in response to the gate-off voltage. In the case of an n-channel transistor, the gate-on voltage can be a gate-high voltage VGH, and the gate-off voltage can be a gate-low voltage VGL. In the case of a p-channel transistor, the gate-on voltage can be a gate-low voltage VGL, and the gate-off voltage can be a gate-high voltage VGH.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Further, the term “can” fully encompasses all the meanings and coverages of the term “may” and vice versa. The term “disclosure” is interchangeably used with, and/or encompasses all the meanings and coverages of, the term “invention.”

All the components of each display device/apparatus according to all embodiments of the present disclosure are operatively coupled and configured.

Hereinafter, various embodiments of the present invention will be described in detail with reference to the accompanying drawings.

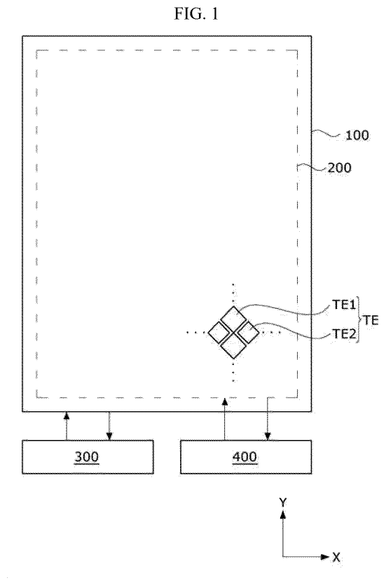

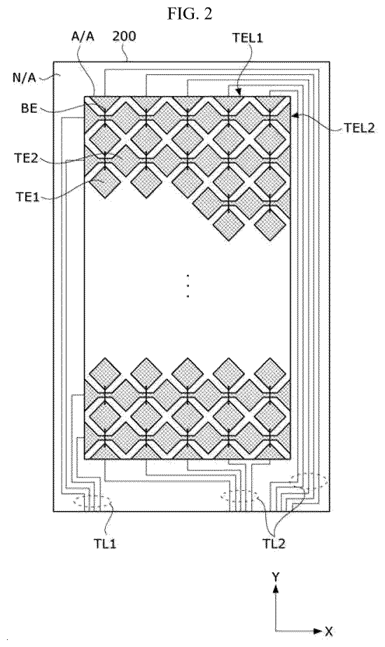

FIG. 1 is a conceptual diagram of a display device according to one or more embodiments of the present disclosure. FIG. 2 is a conceptual diagram of a touch panel according to one or more embodiments of the present disclosure.

Referring to FIGS. 1 and 2, the display device according to the embodiments can provide an image display function for displaying an image and a touch sensing function for sensing a user's touch.

The display device according to the embodiments can include a display panel 100 on which data lines and gate lines are disposed, and a data driver 300 for driving the display panel 100.

The data driver 300 can include a data driving circuit for driving the data lines, a gate driving circuit for driving the gate lines, a controller for controlling the data driving circuit and the gate driving circuit, and the like. The data driver 300 can be implemented with one or more integrated circuits.

The display device according to the embodiment can include a touch panel 200 on which a plurality of touch electrodes TE are disposed and a plurality of touch lines TL1 and TL2 electrically connected to all or some of the plurality of touch electrodes TE are disposed, and a touch circuit unit 400 which drives the touch panel 200 to sense the presence or absence of a touch or a touch position.

The touch circuit unit 400 can supply a touch driving signal to a first touch electrode TE1 to drive the touch panel 200 and detect a touch sensing signal from a second touch electrode TE2 to sense the presence or absence of the touch and/or the touch position (touch coordinates).

The touch circuit unit 400 can include a touch driving circuit which supplies the touch driving signal and receives the touch sensing signal, a touch controller which calculates touch coordinates, and the like. The touch driving signal can be a direct current signal having a constant voltage value, or can also be an alternating current signal which swings between a high level and a low level with a predetermined amplitude and is formed of a plurality of pulses.

The touch circuit unit 400 can be implemented with one or more components (for example, integrated circuits) and can be separately implemented with the data driver 300. However, the embodiments are not limited thereto. All or a portion of the touch circuit unit 400 can be integrated with the data driver 300 and implemented. For example, the touch driving circuit of the touch circuit unit 400 can be implemented with an integrated circuit along with the data driving circuit of the data driver 300.

The touch panel 200 can sense a touch using a mutual-capacitance-based method which is a capacitance-based touch sensing method. In the case of the mutual-capacitance-based touch sensing method, the presence or absence of the touch and/or the touch coordinates can be detected based on a change in capacitance (mutual-capacitance) between a driving electrode and a sensing electrode depending on the presence or absence of a pointer such as a finger, a pen, or the like. However, the embodiments are not limited thereto, and the touch can also be sensed using a self-capacitance-based touch sensing method.

In the case of the self-capacitance-based touch sensing method, each touch electrode TE can serve as both the driving electrode and the sensing electrode.

For example, the touch driving signal can be applied to each touch electrode TE, and the touch sensing signal can be received through the touch electrode TE to which the touch drive signal is applied. Accordingly, in the self-capacitance-based touch sensing method, there is no distinction between the driving electrode and the sensing electrode.

In the self-capacitance-based touch sensing method, the presence or absence of the touch and/or the touch coordinates are detected based on the change in capacitance between a pointer such as a finger, a pen, or the like and the touch electrode TE.

Hereinafter, the mutual-capacitance-based touch sensing method will be described.

The plurality of touch electrodes TE can include the first touch electrode TE1 to which the touch driving signal is applied, and the second touch electrode TE2 which senses the touch sensing signal. The first touch electrode TE1 can be defined as a driving electrode, a touch driving electrode, a driving touch electrode, or the like, and the second touch electrode TE2 can be defined as a sensing electrode, a touch sensing electrode, a sensing touch electrode, or the like.

A plurality of first touch electrodes TE1 can be connected to each other in a second direction (a Y-axis direction) to form a driving electrode line TEL1, and a plurality of second touch electrodes TE2 can be connected to each other in a first direction (an X-axis direction) to form a sensing electrode line TEL2. The plurality of second touch electrodes TE2 can be connected to each other by a bridge electrode BE. However, without being limited thereto, the first touch electrodes TE1 can be connected to each other by the bridge electrode BE.

In the embodiment, the plurality of first touch electrodes TE1 are described as being connected in the second direction, but the present embodiments are not limited thereto. For example, the plurality of first touch electrodes TE1 can be connected to each other in the first direction to form the driving electrode line, and the plurality of second touch electrodes TE2 can be connected to each other in the second direction to form the sensing electrode line.

The touch panel 200 can include the touch lines TL1 and TL2 connected to the touch circuit unit 400 to electrically connect the touch electrodes TE and the touch circuit unit 400. The touch electrodes TE and the touch lines TL1 and TL2 can be disposed on the same layer or on different layers.

The touch panel 200 according to the embodiments can be disposed in the display panel 100, but is not limited thereto. For example, the touch panel 200 can be disposed outside the display panel 100. When the touch panel 200 is an external type, the touch panel 200 and the display panel 100 can be separately manufactured through different panel manufacturing processes and then bonded. When the touch panel 200 is a built-in type, the touch panel 200 and the display panel 100 can be manufactured together through a single panel manufacturing process.

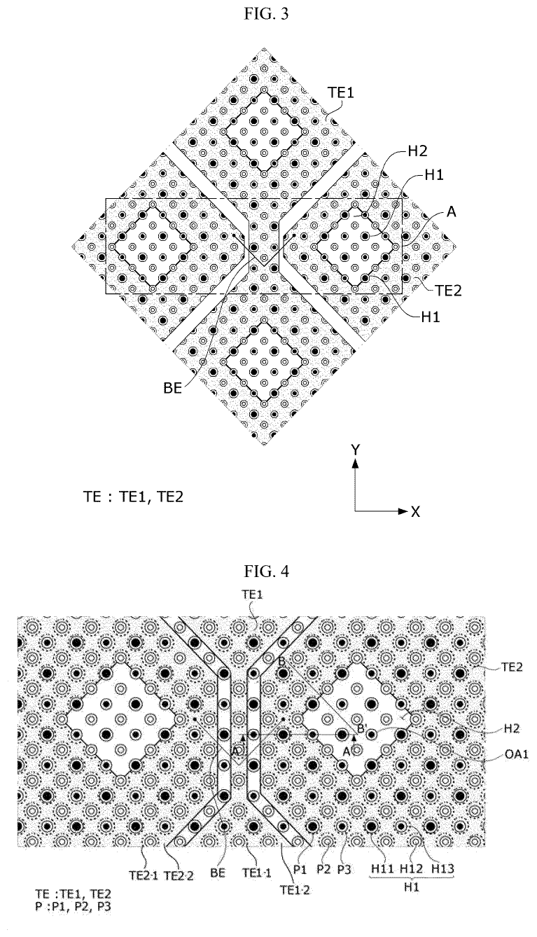

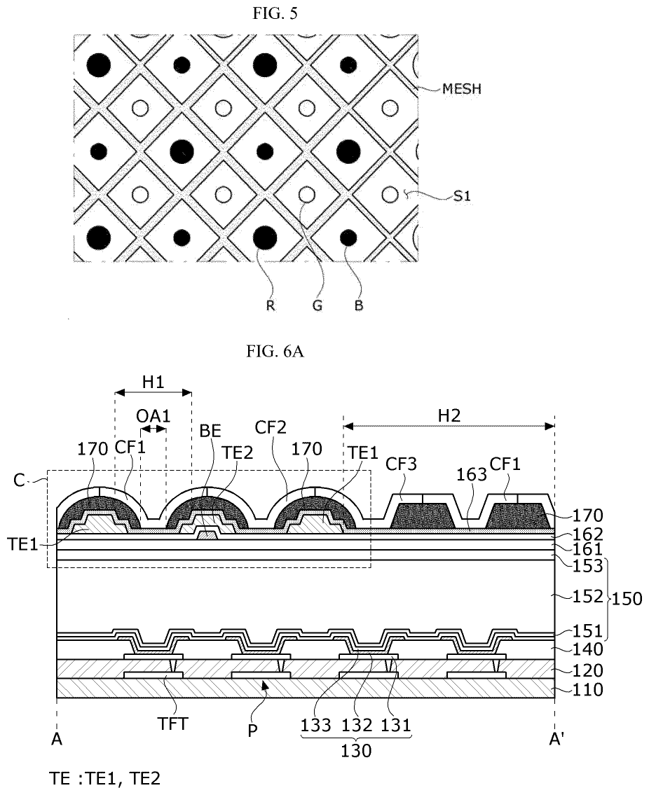

FIG. 3 is a conceptual diagram of the touch electrode according to one embodiment of the present disclosure. FIG. 4 is an enlarged view of region A in FIG. 3. FIG. 5 is a view showing a mesh-type touch electrode.

Referring to FIGS. 3 and 4, the touch electrodes TE can include the first touch electrode TE1 disposed in the first direction and the second touch electrode TE2 disposed in the second direction. The first touch electrode TE1 can be a driving electrode and the second touch electrode TE2 can be a sensing electrode, but the embodiments are not limited thereto. For example, the first touch electrode TE1 can be a sensing electrode and the second touch electrode TE2 can be a driving electrode.

A shape of the touch electrode TE can be a quadrangular shape, but is not limited thereto. For example, the touch electrode TE can have a polygonal shape such as an octagonal shape.

The touch electrode TE can include a first opening hole H1 and a second opening hole H2 which expose a plurality of pixels. The first opening hole H1 can have a size sufficient to expose each pixel P. The first opening hole H1 can have a different diameter depending on a size of the pixel P. The first opening hole H1 can include a 1-1 opening hole H11 which exposes a first pixel P1, a 1-2 opening hole H12 which exposes a second pixel P2, and a 1-3 opening hole H13 which exposes a third pixel P3. For example, when the sizes of the pixels increase in the order of the second pixel P2, the third pixel P3, and the first pixel P1 (P2<P3<P1), the size of the first opening hole H1 can also increase in the order of the 1-2 opening hole H12, the 1-3 opening hole H13, and the 1-1 opening hole H11. For example, the diameter of the first opening hole H1 can vary depending on the size of the pixel. For example, the first pixel P1 can be a red subpixel, the second pixel P2 can be a blue subpixel, and the third pixel P3 can be a green subpixel, but the color of each pixel can be variously modified. When the pixel further includes a white subpixel, the first opening hole H1 can further include a 1-4 opening hole which exposes the white subpixel.

A black matrix 170 can be disposed on the touch electrodes TE. Since the touch electrodes TE are disposed under the black matrix 170, the touch electrode TE may not be visible from the outside. The touch electrodes TE can be disposed as widely as possible in a region where the black matrix 170 is disposed to improve sensing sensitivity.

The black matrix 170 disposed on end of the touch electrode TE can be thinner among thicknesses of the black matrix 170 disposed on the touch electrodes TE near the first opening hole H1. In this case, even when the touch electrodes TE are disposed under the black matrix 170, the reflective visibility of the touch electrode which penetrates the thin black matrix can be a problem.

In order to improve the reflective visibility of the touch electrodes TE, the touch electrode can be formed using a half-tone process.

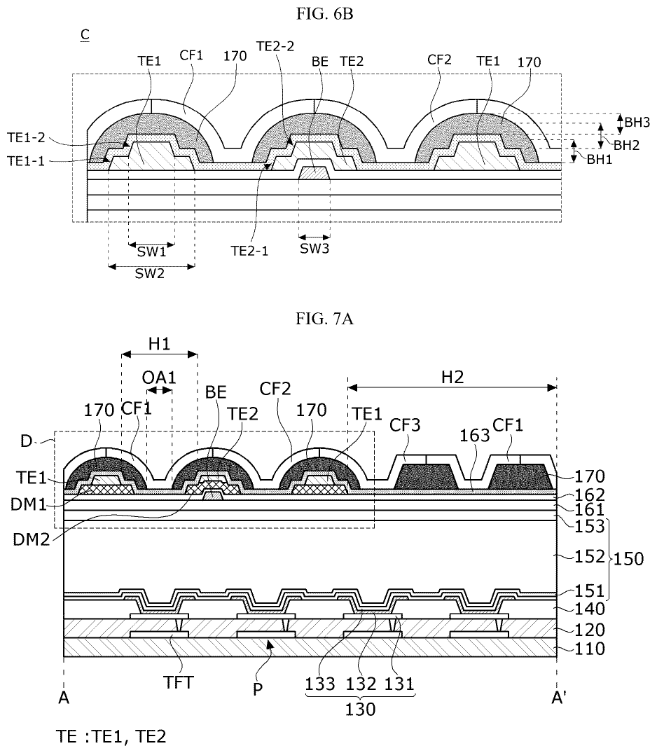

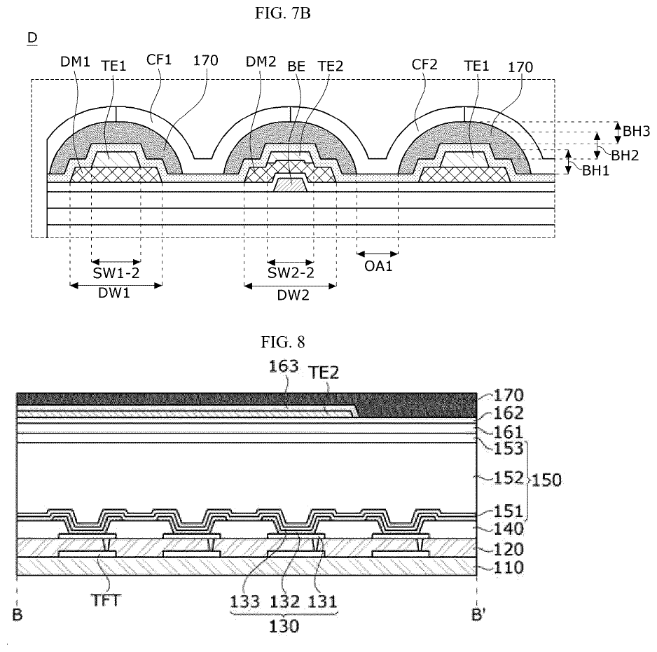

The touch electrodes TE1 and TE2 disposed adjacent to the first opening hole H1 among the touch electrodes TE1 and TE2 using the half-tone process can include lower electrode units TE1-1 and TE2-1 disposed with a thinner thickness. The detailed description of the lower electrode portion TE1-1 and TE2-1 will be described below in FIGS. 6A to 7B in detail.

According to the embodiment, the second opening hole H2 can be formed in the touch electrode TE. The second opening hole H2 can be disposed in a center of the touch electrode TE, but is not limited thereto. For example, the second opening hole H2 can be disposed at an edge of the touch electrode TE. The second opening hole H2 can be divided into a plurality of holes. A total area of the second opening hole H2 in the touch electrode TE can be smaller than a total area of the plurality of first opening holes H1. However, without being limited thereto, the total area of the second opening hole H2 in the touch electrode TE can be larger than or equal to the total area of the plurality of first opening holes H1.

The second opening hole H2 can be formed to adjust the area of the touch electrode TE.

The second opening hole H2 can be formed to correspond to a shape of the touch electrode TE. For example, when the touch electrode TE has a quadrangular shape, the second opening hole H2 can also have a quadrangular shape. However, the embodiments are not limited thereto. For example, the touch electrode TE can have an octagonal shape and the second opening hole H2 can have a quadrangular shape.

Referring to FIG. 5, a touch electrode TE having a mesh structure has been conventionally used for visibility, but there can be a limitation that resistance relatively increases due to a thin mesh line, and thus sensing sensitivity is low. However, according to the embodiment of the present disclosure, since the touch electrodes TE are entirely disposed under the black matrix 170, there is an advantage of disposing the touch electrodes TE as widely as possible to lower the resistance.

FIG. 6A is a cross-sectional view taken along line A-A′ in FIG. 4. FIG. 6B is an enlarged view of region C in FIG. 6A.

Referring to FIGS. 6A and 6B, the display device according to the embodiment can include a substrate 110, a plurality of pixels P disposed on the substrate 110, an encapsulation unit 150 disposed on the plurality of pixels, a plurality of touch electrodes TE disposed on the encapsulation unit 150, and a black matrix 170 disposed on the plurality of touch electrodes TE. Each of the plurality of pixels P can include a light-emitting element 130 and a driving circuit including a thin film transistor TFT.

The substrate 110 can include an insulating material. For example, the substrate 110 can include glass or plastic. A buffer layer can be disposed on the substrate 110. The buffer layer can prevent contamination by the substrate during the formation process of the driving circuit.

The driving circuit including a plurality of thin film transistors TFT can be disposed on the substrate 110. The thin film transistor TFT can generate a driving current corresponding to a data signal. The thin film transistor can be an oxide thin film transistor or a low temperature polycrystalline silicon (LTPS) thin film transistor.

A planarization layer 120 can compensate for a surface step caused by the driving circuit of each pixel. For example, an upper surface of the planarization layer 120 facing the substrate 110 can be a flat plane. The planarization layer 120 can include an organic insulating material. A plurality of insulating layers can be further disposed between the planarization layer 120 and the substrate 110.

The light-emitting element 130 can emit light which represents a specific color. For example, the light-emitting element 130 of each pixel can include a first electrode 131, a light-emitting layer 132, and a second electrode 133 sequentially stacked on the substrate 110.

The first electrode 131 can include a conductive material. The first electrode 131 can include a material having high reflectivity. For example, the first electrode 131 can include a metal such as aluminum (Al) and silver (Ag). The first electrode 131 can have a multilayer structure. For example, the first electrode 131 can have a structure in which a reflective electrode made of metal is positioned between transparent electrodes made of transparent conductive materials such as ITO and IZO.

The light-emitting layer 132 can generate light having brightness corresponding to a voltage difference between the first electrode 131 and the second electrode 133. For example, the light-emitting layer 132 can include an emission material layer EML including an emission material. The emission material can include an organic material, an inorganic material, or a hybrid material. For example, the display device according to the embodiment of the present disclosure can be an organic light-emitting display device including an organic emission material.

The light-emitting layer 132 can have a multilayer structure. For example, the light-emitting layer 132 can include a hole injection layer HIL, a hole transport layer HTL, an electron transport layer ETL, and an electron injection layer EIL.

However, the embodiments of the present disclosure are not limited thereto. The light-emitting element 130 can include an inorganic material light-emitting layer 132. In this case, the light-emitting layer 132 can include a micro-sized inorganic light-emitting layer.

The second electrode 133 can include a conductive material. The second electrode 133 can include a different material from the first electrode 131. The transmittance of the second electrode 133 can be greater than the transmittance of the first electrode 131. For example, the second electrode 133 can be a transparent electrode made of a transparent conductive material such as ITO and IZO. Accordingly, in the display device according to the embodiment of the present disclosure, light generated by the light-emitting layer 132 can be emitted to the outside through the second electrode 133.

The bank layer 140 can be located on the planarization layer 120. The bank layer 140 can define a light-emitting region in each pixel. For example, the bank layer 140 can cover an edge of the first electrode 131. The light-emitting layer 132 and the second electrode 133 can be sequentially stacked on a portion of the first electrode 131 exposed by the bank layer 140. The bank layer 140 can include an insulating material. For example, the bank layer 140 can include an organic insulating material.

At least a portion of the light-emitting layer 132 of each pixel can extend outside the pixel. For example, at least one of the hole injection layer HIL, the hole transport layer HTL, the electron transport layer ETL, and the electron injection layer EIL located in each pixel can extend onto the bank layer 140. At least one of the hole injection layer HIL, the hole transport layer HTL, the electron transport layer ETL, and the electron injection layer EIL located in each pixel can be simultaneously formed with a corresponding layer located in an adjacent pixel. For example, at least one of the hole injection layer HIL, the hole transport layer HTL, the electron transport layer ETL, and the electron injection layer EIL can be formed on the entire surface of the substrate 110.

The encapsulation unit 150 can be located on the light-emitting element of each pixel. The encapsulation unit 150 can prevent damage to the light-emitting element due to external moisture and impact. For example, the light-emitting element 130 of each pixel can be completely covered by the encapsulation unit 150.

The encapsulation unit 150 can have a multilayer structure. For example, the encapsulation unit 150 can include a first encapsulation layer 151, a second encapsulation layer 152, and a third encapsulation layer 153. The first encapsulation layer 151, the second encapsulation layer 152, and the third encapsulation layer 153 can include insulating materials.

The second encapsulation layer 152 can include a different material from the first encapsulation layer 151 and the third encapsulation layer 153. For example, the first encapsulation layer 151 and the third encapsulation layer 153 can include an inorganic insulating material, and the second encapsulation layer 152 can include an organic insulating material. Accordingly, the damage to the light-emitting element due to the external moisture and impact can be effectively prevented.

Since the second encapsulation layer 152 is formed relatively thick, a surface step due to the light-emitting element can be compensate by the second encapsulation layer 152. For example, an upper surface of the encapsulation unit 150 facing the substrate 110 can be a flat plane. Further, a parasitic capacitance between the second electrode 133 of the light-emitting element and the touch electrode TE can be reduced by the second encapsulation layer 152. A thickness of the second encapsulation layer 152 can be 5 μm or more, but is not limited thereto.

A first touch insulating layer 161 can be disposed on the encapsulation unit 150. The first touch insulating layer 161 can block a chemical solution such as a developer or an etchant used in a manufacturing process of the touch electrodes TE, or external moisture or foreign substances from penetrating into the light-emitting element.

The bridge electrode BE can be disposed on the first touch insulating layer 161. The bridge electrode BE can be disposed at a position which connects the plurality of second touch electrodes TE2 among the touch electrodes TE. The bridge electrode BE can include the same material as the touch electrode TE, but can also include different materials.

A second touch insulating layer 162 can be disposed on the first touch insulating layer 161 to cover the bridge electrode BE and insulate the bridge electrode BE from the touch electrode TE. The second touch insulating layer 162 can be disposed between the bridge electrodes BE and can insulate the bridge electrodes BE from each other. Some of the second touch electrodes TE2 can be connected to the bridge electrodes BE by through holes.

The first touch insulating layer 161 and/or the second touch insulating layer 162 can be made of an inorganic insulating material such as silicon nitride (SiNₓ) or silicon oxide (SiOₓ).

The black matrix 170 can include a plurality of opening regions OA1, and the plurality of opening regions OA1 can be disposed at a position overlapping the first opening hole H1 of the touch electrode TE. Accordingly, light emitted from the light-emitting element 130 can be emitted to the outside through the first opening hole H1 and the opening region OA1. The first opening hole H1 of the touch electrode TE can have a wider diameter than the opening region OA1 of the black matrix 170.

For example, a separate touch protection layer 163 can be disposed between the touch electrode TE and the black matrix 170. The touch protection layer 163 can be disposed on the touch electrode TE. The touch protection layer 163 can serve to prevent oxidation, corrosion, or damage to the touch electrode TE and the touch line. The touch protection layer 163 can be made of at least one or more materials among inorganic insulating materials such as silicon nitride (SiNₓ) and silicon oxide (SiOₓ), or organic insulating materials such as an acrylic resin, an epoxy resin, a phenolic resin, a polyamide resin, or a polyimide resin, but is not limited thereto.

On the second opening hole H2 of the touch electrode TE, the black matrix 170 can be disposed on the second touch insulating layer 162. The second opening hole H2 can overlap the plurality of opening regions OA1 of the black matrix 170. For example, one first opening hole H1 overlaps one opening region OA1, but one second opening hole H2 can overlap the plurality of opening regions OA1.

The touch electrodes TE disposed near the first opening hole H1 can be disposed as lower electrode units TE1-1 and TE2-1 and upper electrode units TE1-2 and TE2-2 disposed on the lower electrode units TE1-1 and TE2-1 using the half-tone process.

The upper electrode units TE1-2 and TE2-2 disposed on the lower electrode units TE1-1 and TE2-1 can have a smaller area than the lower electrode units TE1-1 and TE2-1. For example, a length SW2 of each of the lower electrode units TE1-1 and TE2-1 in the first direction can be greater than a length SW1 of each of the upper electrode units TE1-2 and TE2-2 in the first direction. Accordingly, the touch electrodes TE including the lower electrode units TE1-1 and TE2-1 and the upper electrode units TE1-2 and TE2-2 can have a stepped form. For example, the lower electrode units TE1-1 and TE2-1 and the upper electrode units TE1-2 and TE2-2 of the touch electrodes TE can integrally configured. In this case, the upper electrode units TE1-2 and TE2-2 and the lower electrode units TE1-1 and TE2-1 can include the same material.

The black matrix 170 which covers the touch electrode TE can be disposed in a spherical shape. Since the touch electrodes TE are disposed in a stepped form, a second thickness BH2 of the black matrix 170 disposed on the lower electrode units TE1-1 and TE2-1 can be greater than a first thickness BH1 of the black matrix 170 disposed on the encapsulation unit 150 where the touch electrodes TE are not disposed.

Since the black matrix 170 which covers the touch electrodes TE is disposed in a spherical shape, the first thickness BH1 of the black matrix 170 disposed on the encapsulation unit 150 where the touch electrodes TE are not disposed and a third thickness BH3 of the black matrix 170 disposed on the upper electrode units TE1-2 and TE2-2 can be substantially the same.

Color filters CF1, CF2, and CF3 can be disposed in at least the opening region OA1 of the black matrix 170. Color filters having the same color as light emitted from each light-emitting element 130 can be disposed as the color filters CF1, CF2, and CF3, respectively. According to the embodiment, as a plurality of color filters CF1, CF2, and CF3 can be located at positions corresponding to the plurality of opening regions, excellent light-emitting performance can be achieved.

FIG. 7A is a cross-sectional view taken along line A-A′ in FIG. 4 according to another embodiment of the present disclosure. FIG. 7B is an enlarged view of region D in FIG. 7A.

Referring to FIGS. 7A and 7B, lower electrodes TE1-1 and TE2-1 of stepped-shaped electrodes formed to suppress reflective visibility of touch electrodes TE1 and TE2 disposed adjacent to an opening OA1 can be disposed as dummy electrodes DM1 and DM2.

The dummy electrodes DM1 and DM2 are formed to suppress the reflective visibility of the touch electrodes TE1 and TE2 disposed adjacent to the opening OA1, and thus can be disposed in a simple dummy form floated with the touch electrodes TE1 and TE2.

The first and second touch electrodes TE1 and TE2 disposed on the dummy electrodes DM1 and DM2 can be disposed with a smaller area than the dummy electrodes DM1 and DM2. For example, lengths DW1 and DW2 of the dummy electrode DM1 in the first direction can be greater than lengths SW1-2 and SW2-2 of the touch electrodes TE1 and TE2 in the first direction.

A black matrix 170 which covers the dummy electrodes DM1 and DM2 and the touch electrodes TE1 and TE2 can be disposed in a semicircular shape. Since a structure of the dummy electrodes DM1 and DM2 and the touch electrodes TE1 and TE2 is disposed in a stepped form, a second thickness BH2 of the black matrix 170 disposed on the dummy electrodes can be greater than a first thickness BH1 of the black matrix 170 disposed on an encapsulation unit 150 where the dummy electrodes DM are not disposed.

Since the black matrix 170 which covers the dummy electrodes DM1 and DM2 and the touch electrodes TE1 and TE2 is disposed in a semicircular shape, the first thickness BH1 of the black matrix 170 disposed on the encapsulation unit 150 where the dummy electrodes DM are not disposed and a third thickness BH3 of the black matrix 170 disposed on the touch electrodes TE1 and TE2 can be substantially the same or similar to each other.

The dummy electrodes DM1 and DM2 can include a different metal material from the touch electrodes TE. The dummy electrodes DM1 and DM2 can include a metal having a higher transmittance than that of the touch electrode TE. For example, The dummy electrodes DM1 and DM2 can be transparent electrodes made of transparent conductive materials such as ITO and IZO. Since the dummy electrodes DM1 and DM2 are disposed as the transparent electrodes made of the transparent conductive materials such as ITO and IZO, the reflective visibility can be further reduced even when the black matrix 170 is damaged near the opening OA1. Without being limited thereto, the dummy electrodes DM1 and DM2 can be disposed as opaque electrodes such as Ti/Al/Ti.

The black matrix 170 disposed adjacent to a second opening hole H2 which does not cover the dummy electrodes DM1 and DM2 and the touch electrodes TE1 and TE2 can be disposed in a trapezoidal shape as shown in FIG. 7A.

FIG. 8 is a cross-sectional view taken along line B-B′ in FIG. 4.

Referring to FIG. 8, the second touch electrode TE2 not adjacent to the plurality of first openings OA1 and disposed on the second touch insulating layer 162 can be configured as a single electrode rather than as a double layer of a lower electrode unit TE2-1 and an upper electrode unit TE2-2. The second touch electrode TE2, which is spaced apart from the first openings OA1 and configured as single electrode, can be disposed entirely under the black matrix 170. The black matrix 170 disposed not adjacent to the first openings OA1 can be formed with a thickness which sufficiently suppresses reflective visibility even when the touch electrodes TE are disposed with a step between the upper and lower electrodes or is disposed as a single metal electrode rather than a structure using the dummy electrodes.

Although the embodiment shows that the second touch electrode TE2 is disposed entirely under the black matrix 170, the embodiments are not limited thereto. For example, the first touch electrode TE1 can be disposed entirely under the black matrix 170 to increase an area of the touch electrodes, and increase sensing sensitivity.

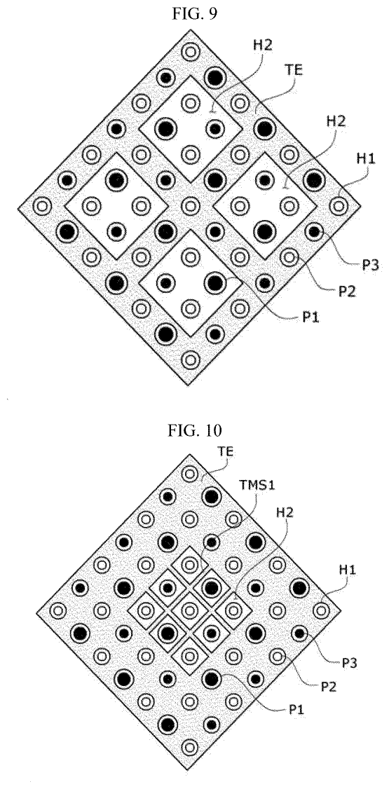

FIGS. 9 to 11 are views showing various modified examples of the touch electrodes.

Referring to FIG. 9, the touch electrode TE can include a plurality of first opening holes H1 and a plurality of second opening holes H2. According to the embodiment, the second opening hole H2 can be divided into a plurality of second opening hole H2 and disposed spaced apart from each other. When the second opening holes H2 are disposed at a predetermined interval, since resistance distribution in the touch electrodes TE becomes more uniform, the sensing sensitivity can be improved.

Referring to FIG. 10, a plurality of conductive lines TMS1 can be formed in the second opening holes H2 of the touch electrode TE. According to the configuration, the sensing sensitivity can be improved by forming the plurality of conductive lines TMS1 in the second opening holes H2 while maintaining a metal density.

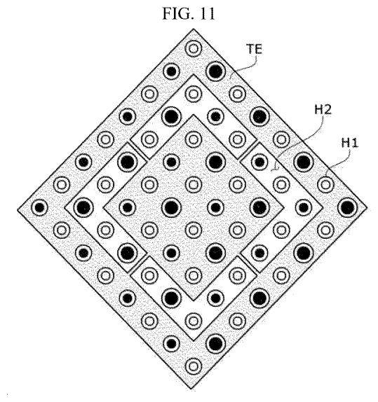

Referring to FIG. 11, the second opening hole H2 can be disposed at an edge of the touch electrode TE. In this case, the second opening hole H2 can be formed by connecting the plurality of first opening holes H1. A width of the second opening hole H2 can be greater than or equal to a diameter of the first opening hole H1. In this way, the position and shape of the second opening hole H2 can be variously modified within a range which satisfies the metal density.

According to one or more embodiments of the present disclosure, low reflectivity is possible and a visibility problem can be improved by disposing touch electrodes under a black matrix in a stepped manner using a half-tone process. Further, sensing sensitivity can be increased by increasing an area of the touch electrodes. In addition, there is an advantage in securing touch performance as the sensor design freedom increases.

The effects of the present disclosure are not limited to the above-mentioned effects, and other effects which are not mentioned can be clearly understood by those skilled in the art from the following description.

Since the content of the specification described the problems to be solved, the problem solving means and the effect to be solved do not specify the characteristics of the appended claims, and the scope of the appended claims is not limited by the matters described in the content of the specification.

Although embodiments have been described in more detail with reference to the accompanying drawings, the present invention is not necessarily limited to these embodiments and can be variously modified without departing from the technical spirit of the present invention. The embodiments disclosed herein, therefore, are not to be taken in a sense for limiting the technical concept of the present invention but for explanation thereof, and the range of the technical concept of the present invention is not limited to these embodiments. Therefore, it should be understood that the above-described embodiments are not restrictive but illustrative in all aspects.

What is claimed is:

1. A display device comprising:
a substrate;
a plurality of pixels disposed on the substrate;
an encapsulation unit disposed on the plurality of pixels; and
a plurality of touch electrodes disposed on the encapsulation unit,
wherein the plurality of touch electrodes include:
a lower electrode unit including a plurality of first opening holes that respectively expose the plurality of pixels; and
an upper electrode unit on the lower electrode unit and having a smaller area than the lower electrode unit.

2. The display device of claim 1, further comprising a black matrix disposed on the plurality of touch electrodes,
wherein the plurality of touch electrodes are disposed to overlap the black matrix.

3. The display device of claim 2, wherein at least one of a first thickness of the black matrix disposed on the encapsulation unit in which the plurality of touch electrodes are not disposed, a second thickness of the black matrix disposed on the lower electrode unit on which the upper electrode unit is not disposed, and a third thickness of the black matrix disposed on the upper electrode unit is different from another thickness among the first to third thicknesses.

4. The display device of claim 3, wherein the second thickness is largest among the first to third thicknesses, and
the first thickness and the third thickness are substantially the same.

5. The display device of claim 1, wherein the plurality of touch electrodes include:
a plurality of first touch electrodes arranged in a first direction; and
a plurality of second touch electrodes arranged in a second direction intersecting the first direction.

6. The display device of claim 5, further comprising a bridge electrode disposed under some of the plurality of touch electrodes, and electrically connecting the plurality of first touch electrodes to the plurality of second touch electrodes, respectively.

7. The display device of claim 6, wherein a first length of the lower electrode unit in the first direction of the display device, a second length of the upper electrode unit in the first direction of the display device, and a third length of the bridge electrode in the first direction of the display device are different from each other.

8. The display device of claim 7, wherein the second length is greater than the first length.

9. The display device of claim 1, wherein the upper electrode unit and the lower electrode unit include a same material.

10. The display device of claim 1, wherein the upper electrode unit and the lower electrode unit include different materials from each other.

11. The display device of claim 10, wherein the lower electrode unit includes a metal having a higher transmittance than a transmittance of the upper electrode unit.

12. The display device of claim 1, wherein the plurality of touch electrodes include a plurality of second opening holes larger than the plurality of first opening holes.

13. The display device of claim 12, wherein one of the plurality of second opening holes exposes more pixels than one of the plurality of first opening holes.

14. The display device of claim 12, wherein a total area of one of the plurality of second opening holes in the corresponding touch electrode is smaller than a total area of the plurality of first opening holes.

15. The display device of claim 12, wherein each of the plurality of first opening holes exposes one pixel, and
sizes of the plurality of first opening holes are different from each other.

16. The display device of claim 2, wherein the upper and lower electrode units are disposed on the encapsulation unit to form stepped sides.

17. The display device of claim 16, wherein the black matrix covers top surfaces and the stepped sides of the upper and lower electrode units.

18. The display device of claim 2, wherein the black matrix covering the upper and lower electrode units has a semicircular shape.

19. The display device of claim 2, further comprising a touch protection layer disposed between the plurality of touch electrodes and the black matrix,
wherein the touch protection layer includes an inorganic insulating material or an organic insulating material.

20. The display device of claim 1, wherein the encapsulation unit is a multilayer structure including a layer having an inorganic insulating material and a layer having an organic insulating material, and
wherein the layer having the organic insulating material is thicker than the layer having the inorganic material.
